(19) United States
(12) Patent Application Publication
(10) Pub. No.: US 2026/0231523 A1
(43) Pub. Date: Aug. 6, 2026

(54) SEMICONDUCTOR STRUCTURE

(71) Applicant: Winbond Electronics Corp., Taichung City (TW)

(72) Inventors: Chih-Han Chen, Tainan City (TW); Wen-Chia Ou, Kaohsiung City (TW); Yu-Feng Cheng, Taichung City (TW); Kai-Hsiang Chang, Taichung City (TW)

(73) Assignee: Winbond Electronics Corp., Taichung City (TW)

(21) Appl. No.: 19/241,360

(22) Filed: Jun. 17, 2025

(30) Foreign Application Priority Data
Feb. 5, 2025 (TW) 114104125

(51) Int. Cl. H10D 84/85; H10B 12/00; H10D 62/10

(52) U.S. Cl. CPC H10D 84/856; H10B 12/50; H10D 62/102

(57) ABSTRACT

A semiconductor structure suitable for a sense amplifier is provided. The semiconductor structure includes a first pair of transistors and a second pair of transistors. The first pair of transistors includes a first P-type transistor and a first N-type transistor electrically connected to each other. The second pair of transistors is electrically connected to the first pair of transistors, and includes a second P-type transistor and a second N-type transistor electrically connected to each other. The channel area of the first P-type transistor is different from the channel area of the second P-type transistor, and/or the channel area of the first N-type transistor is different from the channel area of the second N-type transistor.

### CROSS-REFERENCE TO RELATED APPLICATION

This application claims the priority benefit of Taiwan application serial no. 114104125, filed on Feb. 5, 2025. The entirety of the above-mentioned patent application is hereby incorporated by reference herein and made a part of this specification.

### BACKGROUND

### Technical Field

The present invention relates to a semiconductor structure, and in particular to a semiconductor structure suitable for a sense amplifier.

### Description of Related Art

In the dynamic random access memory (DRAM) device, the signals are pulled up and pulled down through the sense amplifier. The sense amplifier may include two pairs of transistors, and each of the two pairs of transistors includes a P-type transistor and an N-type transistor. In order to stabilize the signals, the threshold voltages of the two pairs of transistors need to be controlled to match as much as possible. That is, the voltage difference of the threshold voltages of the two P-type transistors in the two pairs of transistors is made to be 0 as much as possible, and the voltage difference of the threshold voltages of the two N-type transistors in the two pairs of transistors is made to be 0 as much as possible.

Due to various subsequent processes and routing designs, it is easy to cause the threshold voltages of the two P-type transistors and/or the two N-type transistors in the two pairs of transistors to mismatch during the operation. When the threshold voltages of two transistors do not match too much, the stability of the stored data may be reduced, thus affecting the device performance.

### SUMMARY

The present invention provides a semiconductor structure including two pairs of transistors, wherein two transistors having the same conductivity type in the two pairs of transistors have different channel areas.

The semiconductor structure of the present invention is suitable for a sense amplifier, and includes a first pair of transistors and a second pair of transistors. The first pair of transistors includes a first P-type transistor and a first N-type transistor electrically connected to each other. The second pair of transistors is electrically connected to the first pair of transistors, and includes a second P-type transistor and a second N-type transistor electrically connected to each other. The channel area of the first P-type transistor is different from the channel area of the second P-type transistor, and/or the channel area of the first N-type transistor is different from the channel area of the second N-type transistor.

Based on the above, the semiconductor structure of the present invention includes two pairs of transistors electrically connected to each other, and each pair of transistors includes a P-type transistor and an N-type transistor electrically connected to each other. The channel areas of two transistors having the same conductivity type in the two pairs of transistors are different, so that the threshold voltages of the two transistors during operation may be substantially the same under the influence of various subsequent processes and routing designs.

### BRIEF DESCRIPTION OF THE DRAWINGS

FIGS. 1 to 4 are top views of semiconductor structures according to different embodiments of the present invention.

### DESCRIPTION OF THE EMBODIMENTS

The semiconductor structure of the present invention includes two pairs of transistors electrically connected to each other, and each pair of transistors includes a P-type transistor and an N-type transistor electrically connected to each other. By adjusting the channel areas of the two transistors having the same conductivity type in the two pairs of transistors, under the influence of various subsequent processes and routing designs, the threshold voltages of the two transistors during the operation may be substantially the same, that is, the voltage difference of the threshold voltages of the two transistors may be substantially 0. In this way, when the semiconductor structure of the present invention is applied to a sense amplifier, the mismatch of the transistors may be avoided, thereby improving the stability of the stored data and enhancing the device performance. In the following, “channel area” refers to the area of the overlapping region between the gate and the active area. The semiconductor structure of the present invention embodiment will be described in detail below.

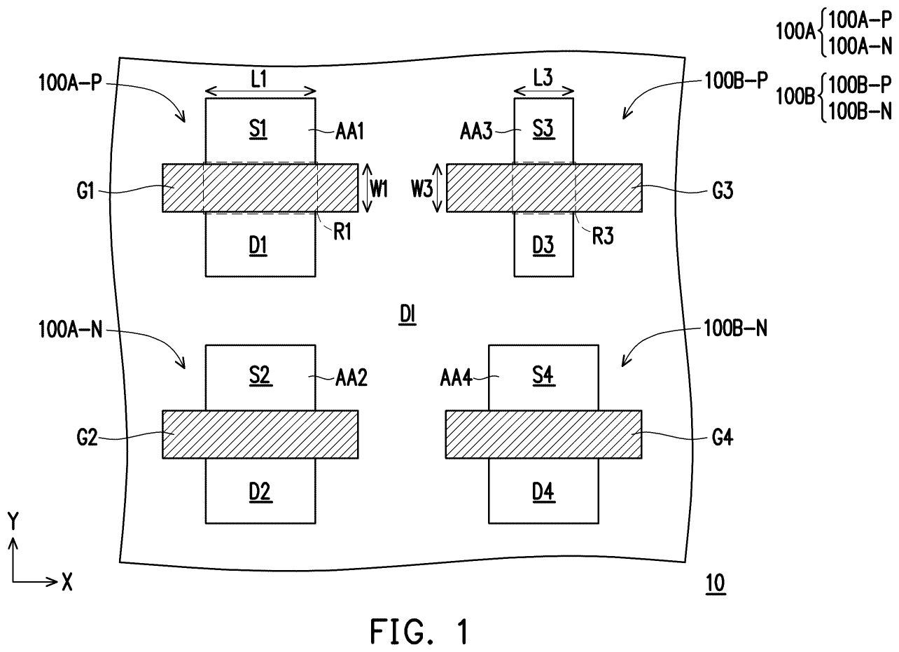

FIG. 1 is a top view schematically showing the semiconductor structure of the first embodiment of the present invention. Referring to FIG. 1, the semiconductor structure 10 of the present embodiment includes a transistor pair 100A and a transistor pair 100B electrically connected to each other. In FIG. 1, the arrangement of the transistor pair 100A and the transistor pair 100B is merely exemplary, and the present invention is not limited thereto.

The transistor pair 100A includes a first P-type metal-oxide-semiconductor (MOS) transistor 100A-P and a first N-type MOS transistor 100A-N electrically connected to each other. The first P-type MOS transistor 100A-P includes a gate G1 extending across an active area AA1 of a substrate, a gate dielectric layer (not shown) located below the gate G1, and a source region S1 and a drain region D1 in the substrate on both sides of the gate G1. In addition, the first N-type MOS transistor 100A-N includes a gate G2 extending across an active area AA2 of the substrate, a gate dielectric layer (not shown) located below the gate G2, and a source region S2 and a drain region D2 in the substrate on both sides of the gate G2. In other words, the transistor pair 100A is a complementary metal-oxide-semiconductor (CMOS) transistor composed of the first P-type MOS transistor 100A-P and the first N-type MOS transistor 100A-N are electrically connected to each other.

The transistor pair 100B includes a second P-type MOS transistor 100B-P and a second N-type MOS transistor 100B-N electrically connected to each other. The second P-type MOS transistor 100B-P includes a gate G3 extending across an active area AA3 of the substrate, a gate dielectric layer (not shown) located below the gate G3, and a source region S3 and a drain region D3 in the substrate on both sides of the gate G3. In addition, the second N-type MOS transistor 100B-N includes a gate G4 extending across an active area AA4 of the substrate, a gate dielectric layer (not shown) located below the gate G4, and a source region S4 and a drain region D4 in the substrate on both sides of the gate G4. In other words, the transistor pair 100B is a CMOS transistor composed of the second P-type MOS transistor 100B-P and the second N-type MOS transistor 100B-N electrically connected to each other.

In FIG. 1, the arrangement of the first P-type MOS transistor 100A-P, the first N-type MOS transistor 100A-N, the second P-type MOS transistor 100B-P and the second N-type MOS transistor 100B-N is merely exemplary, and the present invention is not limited thereto.

The active areas AA1, AA2, AA3, and AA4 are defined by an device isolation structure DI disposed in the substrate. The device isolation structure DI is, for example, a shallow trench isolation (STI) structure formed in the substrate, but the present invention is not limited thereto.

In order to prevent the first P-type MOS transistor 100A-P and the second P-type MOS transistor 100B-P from being affected by various subsequent processes and routing designs, resulting in a voltage difference between the threshold voltages of the two transistors during the operation, through the layout design, the channel area of the first P-type MOS transistor 100A-P is different from the channel area of the second P-type MOS transistor 100B-P, so that the threshold voltages of the two transistors during the operation may be substantially the same. For example, through the layout design, the channel area of the first P-type MOS transistor 100A-P is larger than the channel area of the second P-type MOS transistor 100B-P. In this way, the first P-type MOS transistor 100A-P may have a higher threshold voltage, and the second P-type MOS transistor 100B-P may have a lower threshold voltage. Thereby, under the influence of various subsequent processes and routing designs, the voltage difference between the threshold voltages of the first P-type MOS transistor 100A-P and the second P-type MOS transistor 100B-P during the operation may be substantially 0.

Through the layout design, the first N-type MOS transistor 100A-N and the second N-type MOS transistor 100B-N have the same configuration, so that the first N-type MOS transistor 100A-N and the second N-type MOS transistor 100B-N may match each other. In the following, “same configuration” means that the width, the length and other dimensional parameters of the devices are the same. In addition, in the direction (Y direction) perpendicular to the gate extending direction (X direction), the width W1 of the gate G1 of the first P-type MOS transistor 100A-P is the same as the width W3 of the gate G3 of the second P-type MOS transistor 100B-P, and in the gate extending direction (X direction), the length L1 of the active area AA1 of the first P-type MOS transistor 100A-P is greater than the length L3 of the active area AA3 of the second P-type MOS transistor 100B-P. As a result, the channel area of the first P-type MOS transistor 100A-P (the area of the overlapping region R1 between the gate G1 and the active area AA1) is larger than the channel area of the second P-type MOS transistor 100B-P (the area of the overlapping region R3 between the gate G3 and the active area AA3).

Through the above layout design, after being affected by various subsequent processes and routing designs, the voltage difference between the threshold voltages of the first P-type MOS transistor 100A-P and the second P-type MOS transistor 100B-P during the operation may be substantially 0. That is, the first P-type MOS transistor 100A-P and the second P-type MOS transistor 100B-P may match each other. In this way, when the semiconductor structure 10 is applied to a sense amplifier, the mismatch of the transistors may be avoided, thereby ensuring the stability of data stored in the memory device.

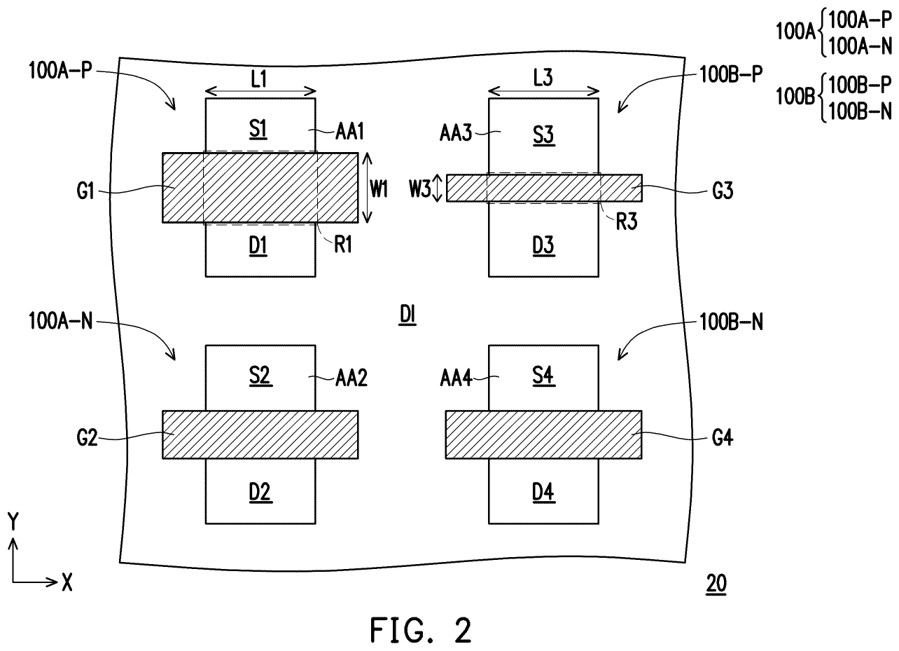

FIG. 2 is a top view schematically showing the semiconductor structure of the second embodiment of the present invention, in which the same devices as those in the first embodiment are denoted by the same reference symbols, and the description thereof will not be repeated.

Referring to FIG. 2, the semiconductor structure 20 of the present embodiment has a similar configuration to the semiconductor structure 10, except that in the semiconductor structure 20, through layout design, in the gate extending direction (X direction), the length L1 of the active area AA1 of the first P-type MOS transistor 100A-P is the same as the length L3 of the active area AA3 of the second P-type MOS transistor 100B-P, and in the direction intersect with the gate extending direction (Y direction), the width W1 of the gate G1 of the first P-type MOS transistor 100A-P is greater than the width W3 of the gate G3 of the second P-type MOS transistor 100B-P. As a result, the channel area of the first P-type MOS transistor 100A-P (the area of the overlapping region R1 between the gate G1 and the active area AA1) is larger than the channel area of the second P-type MOS transistor 100B-P (the area of the overlapping region R3 between the gate G3 and the active area AA3).

Through the above layout design, after being affected by various subsequent processes and routing designs, the voltage difference between the threshold voltages of the first P-type MOS transistor 100A-P and the second P-type MOS transistor 100B-P during the operation may be substantially 0. That is, the first P-type MOS transistor 100A-P and the second P-type MOS transistor 100B-P may match each other. In this way, when the semiconductor structure 20 is applied to a sense amplifier, the mismatch of the transistors may be avoided, thereby ensuring the stability of data stored in the memory device.

In the above embodiments, through the layout design, the channel area of the first P-type MOS transistor 100A-P is different from the channel area of the second P-type MOS transistor 100B-P, thus solving the mismatch of the transistors in the sense amplifier. Similarly, through layout design, the channel area of the first N-type MOS transistor 100A-N may be different from the channel area of the second N-type MOS transistor 100B-N to solve the mismatch of the transistors in the sense amplifier. This will be described below.

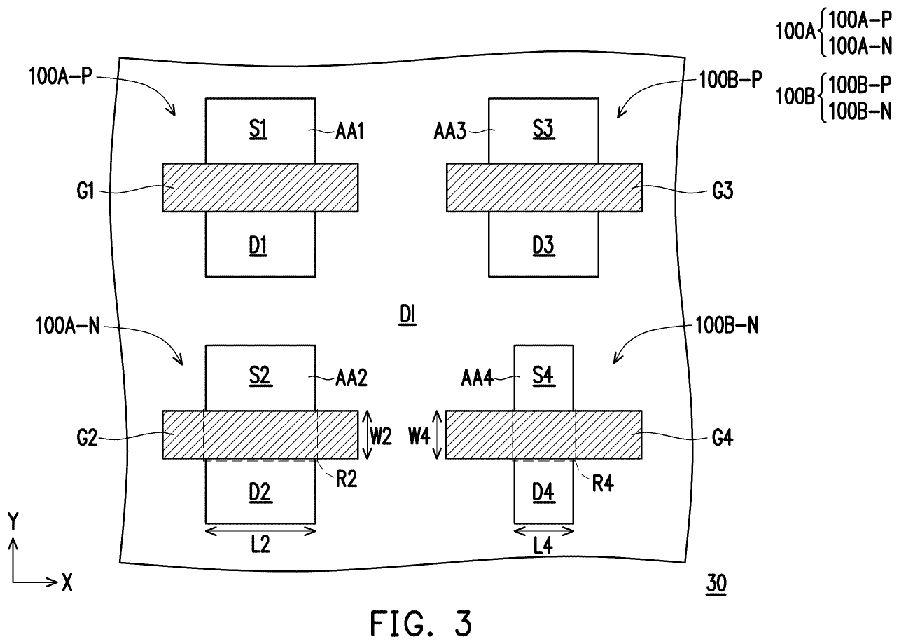

FIG. 3 is a top view schematically showing the semiconductor structure of the third embodiment of the present invention, in which the same devices as those in the first embodiment are denoted by the same reference symbols, and the description thereof will not be repeated.

Referring to FIG. 3, the semiconductor structure 30 of the present embodiment has a similar configuration to the semiconductor structure 10, except that through the layout design, the first P-type MOS transistor 100A-P and the second P-type MOS transistor 100B-P have the same configuration, so that the first P-type MOS transistor 100A-P and the second P-type MOS transistor 100B-P may match each other. In addition, in the direction (Y direction) perpendicular to the gate extending direction (X direction), the width W2 of the gate G2 of the first N-type MOS transistor 100A-N is the same as the width W4 of the gate G4 of the second N-type MOS transistor 100B-N, and in the gate extending direction (X direction), the length L2 of the active area AA2 of the first N-type MOS transistor 100A-N is greater than the length L4 of the active area AA4 of the second N-type MOS transistor 100B-N. As a result, the channel area of the first N-type MOS transistor 100A-N (the area of the overlapping region R2 between the gate G2 and the active area AA2) is larger than the channel area of the second N-type MOS transistor 100B-N (the area of the overlapping region R4 between the gate G4 and the active area AA4).

Through the above layout design, after being affected by various subsequent processes and routing designs, the voltage difference between the threshold voltages of the first N-type MOS transistor 100A-N and the second N-type MOS transistor 100B-N during the operation may be substantially 0, That is, the first N-type MOS transistor 100A-N and the second N-type MOS transistor 100B-N may match each other. In this way, when the semiconductor structure 30 is applied to a sense amplifier, the mismatch of the transistors may be avoided, thereby ensuring the stability of the data stored in the memory device.

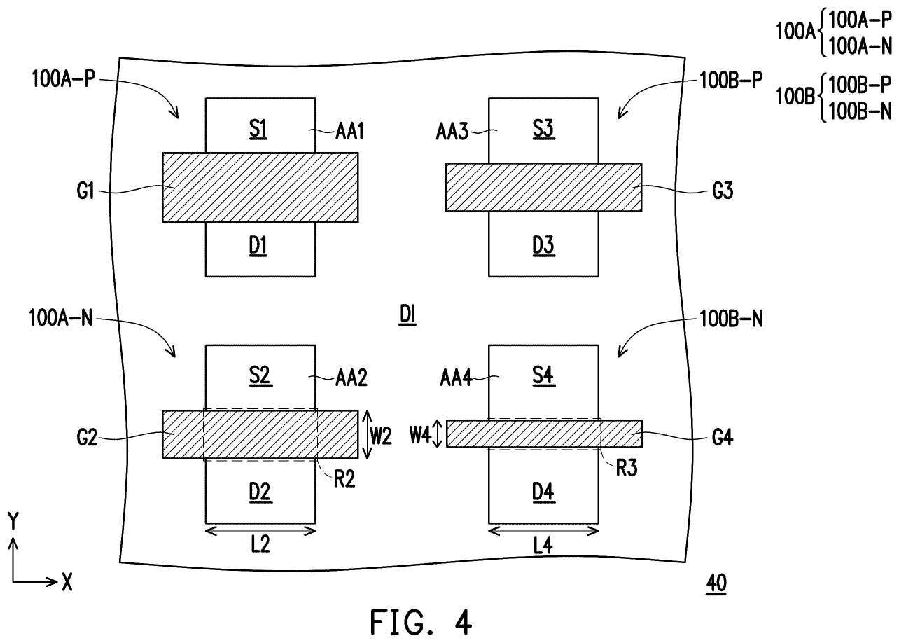

FIG. 4 is a top view schematically showing the semiconductor structure of the fourth embodiment of the present invention, in which the same devices as those in the third embodiment are denoted by the same reference symbols, and the description thereof will be omitted.

Referring to FIG. 4, the semiconductor structure 40 of the present embodiment has a similar configuration to the semiconductor structure 30, except that in the semiconductor structure 40, through layout design, in the gate extending direction (X direction), the length L2 of the active area AA2 of the first N-type MOS transistor 100A-N is the same as the length L4 of the active area AA4 of the second N-type MOS transistor 100B-N, and in the direction intersect with the gate extending direction (Y direction), the width W2 of the gate G2 of the first N-type MOS transistor 100A-N is greater than the width W4 of the gate G4 of the second N-type MOS transistor 100B-N. As a result, the channel area of the first N-type MOS transistor 100A-N (the area of the overlapping region R2 between the gate G2 and the active area AA2) is larger than the channel area of the second N-type MOS transistor 100B-N (the area of the overlapping region R4 between the gate G4 and the active area AA4).

Through the above layout design, after being affected by various subsequent processes and routing designs, the voltage difference between the threshold voltages of the first N-type MOS transistor 100A-N and the second N-type MOS transistor 100B-N during the operation may be substantially 0. That is, the first N-type MOS transistor 100A-N and the second N-type MOS transistor 100B-N may match each other. In this way, when the semiconductor structure 40 is applied to a sense amplifier, the mismatch of the transistors may be avoided, thereby ensuring the stability of the data stored in the memory device.

Depending on actual conditions, the first embodiment to the fourth embodiment may be referred to, and through layout design, the channel area of the first P-type MOS transistor 100A-P may be different from the channel area of the second P-type MOS transistor 100B-P, and at the same time, the channel area of the first N-type MOS transistor 100A-N may be different from the channel area of the second N-type MOS transistor 100B-N.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure suitable for in a sense amplifier, comprising:
a first pair of transistors, comprising a first P-type transistor and a first N-type transistor electrically connected to each other; and
a second pair of transistors, electrically connected to the first pair of transistors, and comprising a second P-type transistor and a second N-type transistor electrically connected to each other,
wherein a channel area of the first P-type transistor is different from a channel area of the second P-type transistor, and/or a channel area of the first N-type transistor is different from a channel area of the second N-type transistor.

2. The semiconductor structure of claim 1, wherein the channel area of the first P-type transistor is greater than the channel area of the second P-type transistor.

3. The semiconductor structure of claim 2, wherein the first P-type transistor has a higher threshold voltage, and the second P-type transistor has a lower threshold voltage.

4. The semiconductor structure of claim 2, wherein in a direction perpendicular to a gate extending direction, a width of a gate of the first P-type transistor is the same as a width of a gate of the second P-type transistor, and in the gate extending direction, a length of an active area of the first P-type transistor is greater than a length of an active area of the second P-type transistor.

5. The semiconductor structure of claim 2, wherein in a gate extending direction, a length of an active area of the first P-type transistor is the same as a length of an active area of the second P-type transistor, and in a direction perpendicular to the gate extending direction, a width of a gate of the first P-type transistor is greater than a width of a gate of the second P-type transistor.

6. The semiconductor structure of claim 1, wherein an channel area of the first N-type transistor is greater than an channel area of the second N-type transistor.

7. The semiconductor structure of claim 6, wherein the first N-type transistor has a higher threshold voltage, and the second N-type transistor has a lower threshold voltage.

8. The semiconductor structure of claim 6, wherein in a direction perpendicular to a gate extending direction, a width of a gate of the first N-type transistor is the same as a width of a gate of the second N-type transistor, and in the gate extending direction, a length of an active area of the first N-type transistor is greater than a length of an active area of the second N-type transistor.

9. The semiconductor structure of claim 6, wherein in a gate extending direction, a length of an active area of the first N-type transistor is the same as a length of an active area of the second N-type transistor, and in a direction perpendicular to the gate extending direction, a width of a gate of the first N-type transistor is greater than a width of a gate of the second N-type transistor.

10. The semiconductor structure of claim 1, wherein the sense amplifier comprises the semiconductor structure, and a threshold voltage of the first P-type transistor is the same as a threshold voltage of the second P-type transistor during an operation of the sense amplifier.

11. The semiconductor structure of claim 1, wherein a voltage difference of a threshold voltage of the first P-type transistor and a threshold voltage of the second P-type transistor is substantially 0 during an operation of the sense amplifier.

12. The semiconductor structure of claim 1, wherein the sense amplifier comprises the semiconductor structure, and a threshold voltage of the first N-type transistor is the same as a threshold voltage of the second N-type transistor during an operation of the sense amplifier.

13. The semiconductor structure of claim 1, wherein a voltage difference of a threshold voltage of the first N-type transistor and a threshold voltage of the second N-type transistor is substantially 0 during an operation of the sense amplifier.

14. The semiconductor structure of claim 1, wherein the first pair of transistors and the second pair of transistors are electrically connected to each other.

15. The semiconductor structure of claim 1, wherein the first P-type transistor comprises a metal-oxide-semiconductor (MOS) transistor.

16. The semiconductor structure of claim 1, wherein the first N-type transistor comprises a MOS transistor.

17. The semiconductor structure of claim 1, wherein the second P-type transistor comprises a MOS transistor.

18. The semiconductor structure of claim 1, wherein the second N-type transistor comprises a MOS transistor.
